(19) United States
(12) Patent Application Publication
(10) Pub. No.: US 2025/0324555 A1
(43) Pub. Date: Oct. 16, 2025

(54) COOLING ARRANGEMENT, CONTROL DEVICE, HEATSINK AND PRODUCTION PROCESS

(71) Applicant: Continental Autonomous Mobility Germany GmbH, Ingolstadt (DE)

(72) Inventor: Andreas Heise, Erzhausen (DE)

(73) Assignee: Continental Autonomous Mobility Germany GmbH, Ingolstadt (DE)

(21) Appl. No.: 18/870,018

(22) PCT Filed: May 25, 2023
(86) PCT No.: PCT/DE2023/200107

§ 371 Date: Nov. 27, 2024

(30) Foreign Application Priority Data
Jun. 2, 2022 (DE) 10 2022 205 647.7

(51) Int. Cl. H05K 7/20

(52) U.S. Cl. CPC H05K 7/20854; H05K 7/20445

(57) ABSTRACT

A cooling arrangement comprising a housing of a control device or a sensor, a component to be cooled arranged in the housing of the cooling arrangement, a first thermal component arranged on the component to be cooled. The housing has a recess into which the first thermal component is inserted in such a way that the first thermal component is mechanically aligned with the component to be cooled and is thermally coupled thereto, and a tolerance-compensating material is provided between the first thermal component and the housing.

### CROSS-REFERENCE TO RELATED APPLICATIONS

The present application is a National Stage Application under 37 C.F.R. 371 of International Application No. PCT/DE2023/200107 filed on May 25, 2023, and claims priority from German Patent Application No. 102022205647.7 filed in the German Patent and Trade Mark Office on Jun. 2, 2022, the disclosures of which are herein incorporated by reference in their entireties.

### BACKGROUND

### 1. Field

Aspects and objects of embodiments of the present application relate to a cooling arrangement, in particular for a sensor system or a control device, a corresponding control device which has a cooling arrangement according to an embodiment, a heatsink for a cooling arrangement according to an embodiment as well as a production process of a cooling arrangement according to an embodiment.

### 2. Description of Related Art

Modem means of transportation such as motor vehicles or motorcycles are increasingly being equipped with driver assistance systems which, with the aid of sensor systems, capture the surroundings, recognize traffic situations and support the driver, e.g., by a braking or steering intervention or by outputting a visual or audible warning. Radar sensors, lidar sensors, camera sensors or the like are regularly deployed as sensor systems for capturing the surroundings. Conclusions can subsequently be drawn about the surroundings from the sensor data established by the sensors, with which, e.g., an object and/or surroundings classification or an environmental model can be created. Furthermore, capturing the surroundings is virtually indispensable in the field of (partial) autonomous driving so there is a particular interest in the advancement and further development of the corresponding systems. As a general rule, electronic control units (ECUs) or control devices are deployed for triggering actuators (brake, engine, transmission and the like) and/or sensors as well as for calculating and controlling driving and assistance functions.

An important aspect of electronic control units is heat dissipation. The heat of the electronic control unit, which is to be dissipated, can be brought outside, e.g., through a housing with good thermal conductivity, e.g., a metal housing, of the control unit. On the surface or at least on, e.g., one side of the housing, there is now the challenge, associated with a high power loss, of conducting the heat away as well as possible so that the parts located in the housing are protected against overheating. There are various forms of cooling, e.g., air cooling, possibly with cooling fins or studs, or a closed coolant circuit which can be connected to the housing of the control unit and overflows a housing wall or its surface.

Generic electronic control units including, in particular, high-performance computing systems, which are also increasingly utilized in modern vehicles or in aviation, are increasingly becoming high-performance computer systems; the systems have to function in ambient temperatures or with coolant temperatures of, e.g., −40 to 65° C. or more. By way of contrast, however, some electronic parts in the control units, in particular data storage modules, e.g., RAM (Random Access Memory) or flash modules or EEPROMs (Electrically Erasable Programmable Read-Only Memory), are frequently very restricted in terms of the upper permissible temperature. Furthermore, in particular thanks to ever faster data transfer speeds, but also thanks to voltage drops which should be avoided or a tendency to oscillate, fast data storage modules are to be located as close as possible to the microprocessors or high-performance processors (in particular CPUs, GPUs, switches, ICs or the like) controlling them, since it is only a location close to the high-performance processors which, for the most part, makes possible the required fast writing and reading speeds or communication speeds. As a general rule, the high-performance processors generate considerable waste heat which, in standard applications, can substantially heat significantly more heat-sensitive parts in the immediate vicinity of the high-performance processors and thus the heat has to be transported away. As the power loss, in particular of the high-performance processors, increases, neighboring parts are consequently increasingly subjected to thermal stress or the cooling systems have to become more and more complex in order to conduct heat away from the generators and the adjacent more sensitive parts.

According to the current prior art, heatsinks are attached to the high-performance processors and to the surrounding parts in order to cool these down to permissible temperatures. One method of dissipating heat at corresponding heat hotspots involves using so-called “heat pipes” which allow a high heat flux density, utilizing the enthalpy of evaporation of a medium and, as a result, can transport heat away effectively.

The heat of the high-performance processor core is often conducted away via a metallic processor housing (LID) of the processor, which also protects the processor core against mechanical damage, and via a tolerance-compensating internal Thermal Interface Material (TIM) which is applied between the chip (core) and LID. The casing of a semiconductor chip or of a “die” or “IC (integrated circuit) module” including the connection points (pins, balls or leads) is referred to as a processor housing (LID) or chip housing (or package). If the cooling is to be connected to a common control unit housing, the metallic processor housing is connected to the metal housing (as a general rule, an aluminum housing) via a further layer, a tolerance-compensating “Thermal Interface Material” (TIM) (paste, adhesive or heat-conducting mat). The aluminum housing is provided, e.g., with cooling fins for air cooling or with ducts for fluid cooling, which can transport the heat away. The relatively thick TIM layers can have a disadvantageous effect since, for the most part, the material has significantly poorer thermal conductivity than, e.g., aluminum and copper, which is frequently also used in the housings and, for tolerance compensation reasons, has to bridge thicknesses from a few hundred micrometers to a few millimeters. Correspondingly, a temperature drop takes place across the TIM (as a general rule, in the range of multiple degrees Celsius). In addition, a temperature drop occurs on the processor housing—depending on the thickness, type and compression of the material, likewise of multiple degrees Celsius. Such temperature drops bring about an enormous restriction in performance.

There is thus a particular need for solutions in order to decrease temperature drops thanks to the values given by material constants. To this end, some constructive solutions are already known in order to realize TIM layers which are as thin as possible via tolerance chains and/or to increase the areas for heat transfer as much as possible in order to decrease the thermal resistance. However, the disadvantage is the increased temperature on the processor or on the processor housing, as a result of which adjacent parts, which themselves generate little waste heat, are heated to a greater extent.

Various TIM materials are known from DE 11 2007 002 317 T5. Furthermore, DE 11 2007 002 317 T5 deals with the problem that integrated circuit apparatuses (IC apparatuses) generate large quantities of thermal energy during operation, which negatively influence their performance and which can cause damage via various mechanisms if said thermal energy is not dissipated. An arrangement having an integrated circuit (IC arrangement) is disclosed, comprising a first thermal component (or passive cooling arrangement) which is arranged next to the IC arrangement and a TIM which is arranged between the IC arrangement and the first thermal component and is in each case thermally coupled to the IC apparatus and the first thermal component. Furthermore, a second thermal component is provided, which is thermally coupled to the first thermal component. A passive cooling arrangement can be provided as the first thermal component, and an active cooling arrangement or a second passive cooling arrangement can be provided as the second thermal component.

### SUMMARY

Aspects and objects of embodiments of the present application relate to a generic cooling arrangement, with which a good removal of heat between a thermal component (or heatsink or cooling element) and a component to be cooled (or the subassembly components to be cooled) is achieved and the disadvantages resulting from the prior art are overcome in a simple, space-saving and inexpensive manner.

According to an aspect of an embodiment, there is provided a colling arrangement including a housing, in particular a control device housing or a sensor housing, a component to be cooled, which is arranged in the housing of the cooling arrangement or control device housing, and a first thermal component which is arranged on the component to be cooled. Furthermore, the housing has a recess into which the first thermal component is inserted in such a way that the first thermal component and the component to be cooled are thermally coupled and mechanically aligned with one another, in particular without larger distances. According to the embodiment, a tolerance-compensating material is provided between the first thermal component and the housing, which brings about the fixing of the first thermal component (or of the heatsink). Thanks to the cooling arrangement according to the embodiment, the thickness of the TIM layer or layers and/or the number of the TIM layers can be reduced to the effect that the heat transfer from the component to be cooled to the first thermal component or the heatsink is improved to a particular extent. Surprisingly, it has been shown that thanks to the new cooling arrangement, the TIM layer only has to be applied very thinly, or can even be omitted entirely.

According to a particularly preferred embodiment of the cooling arrangement, the tolerance-compensating material (in particular fastening material) is, in particular following or during mounting, a hardening material such as, by way of example, an adhesive, resin, epoxy or the like, which preferably cannot or can only be slightly compressed. Advantageously, the tolerance-compensating material is applied in a liquid state or a paste-like state to the edge of the recess on the housing or also the first thermal component or the heatsink (or to its collar). The first thermal component is only fixed in the recess by the hardening of the tolerance-compensating material. In addition, the tolerance-compensating material thereafter creates a stable connection between the first thermal component or heatsink and housing, which makes it possible for forces which act on the first thermal component or the heatsink to be transferred to the housing and not to a comparatively sensitive component to be cooled or processor apparatus. As a result, the component to be cooled can be protected to a particular extent against mechanical force effects which can occur, by way of example, during an impact or a fall.

Furthermore, a second thermal component can be provided, which is arranged on the housing and/or the first thermal component in order to dissipate heat from the first thermal component. As a result, the heat regulation or the cooling can be carried out even more effectively. According to a preferred embodiment, a TIM or a TIM layer can be arranged between the first and second thermal component and/or a TIM or a TIM layer can be arranged between the first thermal component and the component to be cooled.

The first thermal component is preferably embodied as a heatsink or “heat spreader” which is manufactured, e.g., from a metal, in particular copper and/or aluminum and/or an alloy thereof. According to a particularly preferred embodiment, the heatsink can also consist of an aluminum-copper composite material and can be manufactured, e.g., as a so-called extruded part. Such an embodiment can be particularly well suited since the aluminum can be deployed in a particularly flexible manner (e.g., in a compatible manner with the aluminum parts which are deployed in cooling water circuits) and the copper has excellent thermal conduction properties, so that the advantages of both materials can be combined.

The heatsink can expediently have a collar, wherein the tolerance-compensating material is arranged on the collar, i.e., between the collar of the heatsink and the edge of the recess. As a result, the heatsink can be fitted particularly well into the recess.

Alternatively, the heatsink can also have a rhombohedral or trapezoidal cross-section. Said embodiment of the heatsink is particularly well suited to recesses in which no clearly definable edge (e.g., thanks to unevennesses or unclean processing) is provided, since the cross-section of the rhombohedron or trapeze, which tapers in profile, can adapt to various sizes and cross-sections of a recess.

Furthermore, the heatsink can also have cooling fins or cooling studs on the top, i.e., on the side facing away from the part to be cooled or the component to be cooled.

According to an aspect of an embodiment, the second thermal component can comprise a “heat pipe” or fluid cooling, in particular water cooling with fluid ducts or air cooling with cooling fins or a fluid plate with fluid ducts. Moreover, other passive and active cooling systems known from the prior art can also be provided as the second thermal component.

The second thermal component is preferably an elastic bellows or a cooling pad, which is at least partially manufactured from flexible material, so that the second thermal component or a flexible part of the second thermal component nestles against the first thermal component. Due to the flexible property of the heatsink material, it nestles against the components to be cooled, in particular during expansion (e.g., when said heatsink material is filled with fluid). At the same time, the second thermal component can also nestle against housing parts and, thanks to the component-related flexibility, can nestle against components lying on different levels, such as, e.g., the housing and heatsink, at the same time, without the TIM which fills the tolerance gap having to be provided.

Metal film, in particular aluminum film or copper film, and/or plastic film and/or a laminate and/or a composite film, which in particular comprises a metal film and at least one plastic film, can be expediently provided as the flexible material since such films can be produced and processed in a simple and cost-effective manner. As a result of a composite film or a laminate being provided as the flexible material, the durability and stability of the heatsink can be easily improved. In addition, the heatsink can be adapted, as a result, to the properties of the respective cooling medium or to the surrounding conditions. Furthermore, the flexible material can also have a coating, in particular an aluminum coating, in order to improve the properties in terms of stability, tightness, aging and durability. In particular, “anoxal” layers (“anoxal” process =an aluminum oxide layer is created on the surface of the aluminum by anodic polarization of the aluminum) or “eloxal” layers (“eloxal” process =electrolytic oxidation of aluminum, wherein an oxidic protective layer is created on aluminum by anodic oxidation) are also particularly suitable as the coating of an aluminum film.

Furthermore, the second thermal component can be filled with a cooling medium or can be flowed through by a cooling medium, wherein a fluid, in particular water, glycol, a water/glycol mixture, air, CO2 or the like, is provided as the cooling medium.

Additional tolerance-compensating material can also be expediently provided, which compensates for tolerances and is arranged between the first thermal component and the second thermal component and/or a circuit board, which carries the component to be cooled, and/or the component to be cooled. This can improve the protective effect of the component to be cooled even further.

The component to be cooled can be expediently at least one circuit board and/or a printed circuit board (PCB) and/or a microcontroller and/or a processor and/or a chip and/or an integrated circuit (IC) and/or a semiconductor part and/or a circuit carrier and/or a battery and/or other electronic part components.

In a practical manner, the housing can be a housing of a control device or of a sensor for capturing the environment. In particular, aspects of the embodiments relate to a control unit or a control device or a sensor, wherein a cooling arrangement according to the embodiment is provided for cooling the component to be cooled.

In a similar manner to cooling a component to be cooled, the embodiment can of course also be used for tempering or heating a component to be heated.

Furthermore, aspects of the embodiments relate to a process for producing a cooling arrangement, wherein the following process steps are performed (wherein it is not absolutely essential that these are performed in the indicated order): providing (I) a housing, in particular a housing of a control device, which has a recess, or if said housing does not have a recess, optionally producing (II) a recess, mounting (III) the component to be cooled in the housing of the control device, applying (IV) an, in particular, hardening tolerance-compensating material in order to secure the heatsink on the housing of the control device or at the edge of the recess, introducing (VI) the heatsink into the recess and aligning the heatsink with the position of the component to be cooled, and preferably hardening the tolerance-compensating material in order to fix the heatsink.

Furthermore, the production process according to the embodiment can expediently comprise the process step of applying (V) a TIM to the component to be cooled, wherein said process step should be carried out, in a practical manner, prior to introducing (VI) the heatsink into the recess. The TIM used here can preferably be applied as a paste, liquid or as a thinly applied pad.

In this case, it is not absolutely essential that the individual process steps are carried out in the indicated order. For example, it is also possible to not carry out the application (III) of the tolerance-compensating material until after the components to be cooled have been mounted (IV) in the housing of the control device. Furthermore, according to aspects of the embodiments, the housing has multiple recesses and multiple first thermal components or heatsinks in order to cool multiple parts.

Advantageously, aspects of the embodiments ensure that the main heat generator or the component to be cooled and the neighboring components thereof (other parts such as, e.g., memories, transistors, batteries or the like) are thermally decoupled since these are not connected to the heatsink or the first thermal component and the heatsink is also only thermally coupled to the housing to a small extent.

Furthermore, according to an aspect of an embodiment, there is provided a heatsink for a cooling arrangement or for a control device, wherein the heatsink is manufactured from an aluminum-copper composite material and by means of a forming process, in particular by means of extrusion. In a practical manner, the composite material can combine the advantages of aluminum and copper in one part which, surprisingly, can be easily produced by a forming process. For example, a heatsink can be created for liquid cooling, which has copper or a copper alloy toward the component to be cooled since copper has excellent thermal conduction properties, and has aluminum or an aluminum alloy toward the fluid cooling since aluminum is very robust and, in addition, likewise has good thermal conduction properties with regard to the respective fluid. As a result, the cooling can be improved to a particular extent.

### BRIEF DESCRIPTION OF THE DRAWINGS

Aspects and objects of the embodiments are explained in greater detail below with reference to expedient exemplary embodiments, in which:

FIG. 1 is a diagram illustrating a simplified schematic representation of an embodiment of a vehicle having a control device according to an embodiment;

FIG. 2 is a diagram illustrating a simplified representation of a control device according to the prior art;

FIG. 3 is a diagram illustrating a simplified representation of a control device according to an embodiment;

FIG. 4 is a diagram illustrating a simplified representation of the control device according to an embodiment;

FIGS. 5a-5h are diagrams illustrating a simplified representation of a heatsink according to an embodiment;

FIGS. 6a-6f are diagrams illustrating a simplified representation of the transition between the heatsink and the control device housing, according to an embodiment;

FIG. 7 is a diagram illustrating a simplified representation of the control device according to an embodiment;

FIG. 8 is a diagram illustrating a simplified representation of the control device according to an embodiment;

FIG. 9 is a diagram illustrating a simplified representation of the control device according to an embodiment;

FIGS. 10a-c are diagrams illustrating a simplified representation of a heatsink according to an embodiment, and

FIG. 11 are process diagrams illustrating a simplified representation of the production process according to an embodiment.

### DETAILED DESCRIPTION OF THE EMBODIMENTS

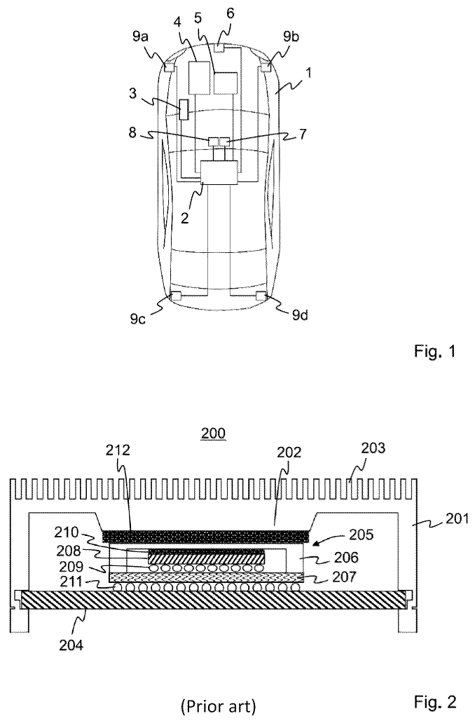

Reference numeral 1 in FIG. 1 denotes a vehicle having various actuators (steering 3, engine 4, brake 5), which has a control device 2 according to the embodiment (ECU, Electronic Control Unit or ADCU, Assisted and Automated Driving Control Unit), by means of which a (partially) automated control of the vehicle 1 can be carried out, e.g., in that the control device 2 can access the actuators of the vehicle 1.

In addition, the control device 2 has a storage unit in order to store, e.g., an algorithm, control instructions or patterns. Furthermore, the vehicle 1 has sensors for capturing the environment: a radar sensor 6, a lidar sensor 7 and a front camera 8 as well as multiple ultrasonic sensors 9a-9d, the sensor data of which are utilized for recognizing the environment and objects so that various assistance functions such as, e.g., Electronic Brake Assist (EBA), Adaptive Cruise Control (ACC), lane keeping control or a Lane Keep Assist (LKA), a parking assistant or the like can be realized. The assistance functions are executed, e.g., via the control device 2 or the algorithm saved therein. In this case, the cooling arrangement according to the embodiment can, in principle, be implemented in each of the sensors or control units or the control device 2.

A control device 200 according to the prior art is shown in FIG. 2. The control device 200 comprises a control unit housing 201 having an integrated heatsink 202 as well as cooling fins 203 on the top of the control device housing 201. The heatsink 202 serves to dissipate the power loss, which occurs in the form of heat, of a processor apparatus 205 arranged on a circuit board 204 by conducting the heat via the heatsink 202 to the cooling fins 203, wherein the cooling fins 203 are cooled down via an air flow. In this case, the processor apparatus 205 comprises an LID or processor housing 206 and a substrate 207 on which the actual processor 208 as well as possible additional parts are arranged with the aid of soldering beads or soldering material or solder 209. In addition, a layer of TIM 210 (Thermal Interface Material; e.g., thermally conductive paste), which is a few 100 micrometers thick, is arranged between the processor housing 206 and the processor 208 so that the heat of the processor 208 can be emitted via the thermally conductive paste and the processor housing 206. The substrate 207 of the processor apparatus 205 is applied to the circuit board 204 via soldering beads or solder 211.

Furthermore, a layer of tolerance-compensating TIM 212, which is a few micrometers to a few millimeters thick, is applied to the processor housing 206; in particular the TIM layer is 10 μm-5 mm, preferably 20 μm-2 mm, preferably 30 μm-1 mm, preferably 40 μm-750 μm and, particularly preferably, 50 μm-500 μm thick. In this case, the TIM layers have, a significantly poorer thermal conductivity than the housing 201 which is manufactured, e.g., from aluminum and copper. Correspondingly, a temperature drop in the range of multiple degrees Celsius takes place across the TIM. Such temperature drops bring about an enormous restriction in performance. For example, the core of the processor 208 may, e.g., reach a maximum temperature of 125° C., i.e., it may, e.g., only reach a temperature of 110° C., at full load, if it is arranged on the processor housing 206 since the temperature drop at the TIM 210 in the processor housing 206 already brings said losses with it. If a few degrees are then lost again at the layer of TIM 212 between the processor housing 206 and the control unit housing 201, the control unit housing 201 must already be kept a few degrees Celsius (e.g., 15° C.) below 110° C. (e.g., in the event of a 15° C. temperature drop, at 95° C. on the housing). Furthermore, the housing material also has a significant thermal resistance to the cooling medium (air or liquid), which can, e.g., also be 15° C. This means that, e.g., at a maximum temperature of 125° C. on the silicon of the processor 208, a maximum of 80° C. might prevail at the transfer to the cooling medium. Any additional disadvantageous temperature drops and non-linear effects are not yet taken into account.

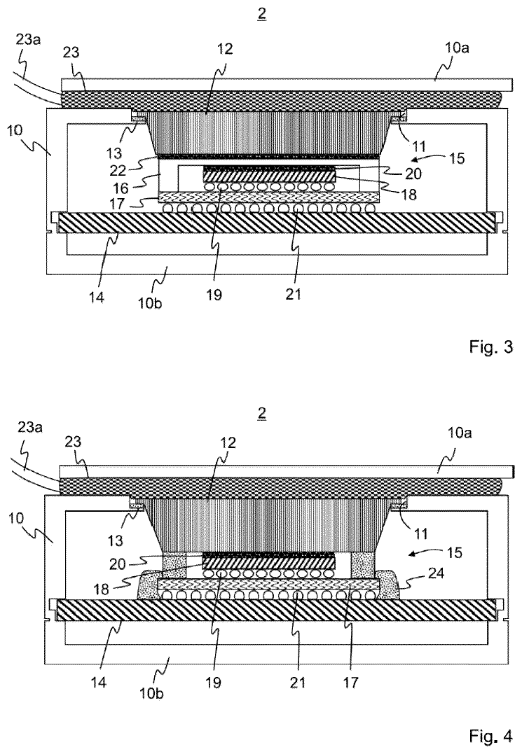

FIG. 3 shows an embodiment of a control device 2 according to the embodiment, which comprises a control device housing 10 having a cover 10a. The first thermal component or the heatsink 12 is arranged in a recess 11 in the control device housing 10 and serves to dissipate the power loss, which occurs in the form of heat, of a processor apparatus 15 which is arranged on a circuit board 14. In this case, the circuit board 14 can carry further part components such as, by way of example, SMD modules, RAM modules, EEPROMs, memories, capacitors, semiconductor parts and the like (not depicted in the figures for the sake of simplicity), which either have to be cooled as well or do not have to be cooled.

The recess 11 is slightly larger than the dimensions of the heatsink 12 and is located in the region or the alignment of the component to be cooled or of the processor apparatus 15, so that the heatsink 12 can be inserted with a sufficient distance from the edge of the recess 11. The recess 11 preferably has an edge on which a part of the heatsink 12 is arranged at a distance, wherein a hardening tolerance-compensating material 13, e.g., an adhesive or a paste or another fixing medium, is applied in order to secure the heatsink 12 on the housing of the control device 2 or at the edge of the recess. During mounting or production, the tolerance-compensating material 13 is applied in the liquid/paste-like state to the edge of the recess 11 or to a collar of the heatsink 12 and the heatsink 12 is subsequently introduced or plugged/mounted into the recess 11. The mounting is carried out in such a way that the fixing of the heatsink 12 is only carried out by hardening or drying of the tolerance-compensating material 13. In a practical manner, the heatsink 12 then sits embedded in the tolerance-compensating material in the recess 11, wherein mechanical force inputs on the heatsink 12 are transferred to the control device housing 10, e.g., by impacts, via the edge of the recess 11 and the solid tolerance-compensating material 13, and not to the comparatively sensitive processor apparatus 15, as a result of which said processor apparatus is protected to a particular extent against mechanical influences. In this case, the tolerance-compensating material 13 can also constitute a seal against dirt and liquids. The tolerance-compensating and fixing medium (for the most part, adhesive) consequently supports the heatsink 12 so that forces, which act on the heatsink 12 following hardening, are mechanically absorbed by the control device housing 10 and, consequently, the part to be cooled is protected against harmful effects (deformation/force action) caused by mechanical stress or force input. In particular, if a thermal partitioning from other housing parts is desired, the hardening adhesive (tolerance-compensating material 13) can leave a wider gap free between the heatsink 12 and the housing and/or can be selected from poorly thermally conductive material if it fills up the gap, in order to decrease the heat transfer.

During the insertion of the heatsink 12, e.g., a previously applied layer of TIM 22 is also displaced on the component to be cooled or the processor apparatus 15 to a large extent, so that said layer is only very thin or no longer present at all. In particular, the layer of TIM 22 in FIG. 3, like the TIM layers in the following figures, is explicitly not drawn to scale, since the TIM layers are depicted significantly thicker for the sake of simplicity. The heatsink 12 is preferably manufactured from metallic material, in particular from aluminum or copper or alloys thereof. Here, a preferred form of production of the heatsink 12 can be extrusion which allows components having good thermal conductivity to be used. In addition, the processor apparatus 15 comprises an LID or processor housing 16 and a substrate 17, on which the actual processor 18 or chip or IC module is arranged with the aid of soldering beads or soldering material or solder 19. In addition, a layer of TIM 20 (Thermal Interface Material; e.g., thermally conductive paste) is arranged between the processor housing 16 and the processor 18 so that the heat of the processor 18 can be emitted via the thermally conductive paste and the processor housing 16. The substrate 17 of the processor apparatus 15 is applied to the circuit board 14 via soldering beads or solder 21. Alternatively, said connection could also be carried out via an adhesive connection or another type of fastening known from the prior art. For reasons of robustness, further constituents such as, e.g., an underfill or corner bond of the process can additionally be present in control devices according to known standards. The circuit board 14 is fixed or clamped, for example between the control device housing 10 and a bottom or cover 10b, or otherwise fastened to the housing, wherein the cover 10b can also close off the control device 2, e.g., in a dustproof and waterproof manner.

In FIG. 3, the second thermal component provided is not a conventional, solid, metallic heatsink, e.g., having cooling fins as in FIG. 2, which are, as a general rule, attached to the components to be cooled with small distances or gaps, for the most part with the aid of thermally conductive pastes in order to constitute a thermal connection to a body through which cooling fluid flows. In this case, reference numeral 23 designates a flexible cooling pad through which fluid flows, or a second thermal component through which fluid flows, which “nestles” against the parts to be cooled, i.e., here against the heatsink 12 and also against the control device housing 10. The cooling pad 23 is arranged between the control device housing 10 and a cover 10a (also holder or other) which is to be optionally provided. The cooling pad 23 can also receive larger pressures (thanks to the support outwardly) but, in particular, thanks to the support on both sides and can nestle against the material of the outer casing. The cooling pad 23 comprises a heatsink which is at least partially manufactured from flexible material or film or composite film. In a practical manner, metal film such as, e.g., aluminum film or copper film, which preferably forms a laminate with a thin plastic film, or plastic film which can be coated/vaporized, e.g., with aluminum or an anodized aluminum film, can be provided as the flexible material. Furthermore, plastic coatings of the aluminum film can also be provided on one or both sides. Moreover, so-called drypack films (antistatic, water vapor-impermeable and flexible barrier films for electronic parts) can also be provided as the flexible material or combinations of the indicated materials. If, in this case, a metal film, in particular an aluminum film, is used, any electrical insulation which may be necessary, but also corrosion resistance, can be ensured by a very thin plastic coating or an “anoxal” or “eloxal” coating. Furthermore, at least one fluid duct 23a for the inflow and outflow of fluid (coolant, air, water or the like) is, in each case, provided.

An embodiment of the control device 2 is shown in FIG. 4, in which the processor apparatus 15 does not have a processor housing. In this case, the cooling apparatus can contact the processor 18 directly or via a thin layer of TIM 20. In this case, the processor housing is also not necessary since the aim is to protect the processor 18 against mechanical influences, which, according to FIG. 4, is effected by the cooling arrangement according to the embodiment since the heatsink 12 will transfer forces, which act on it, to the control device housing 10 via the tolerance-compensating material 13. As additional protection of the processor 18 against mechanical influences, hardening tolerance-compensating material 24 can also be provided between the heatsink 12 and the substrate 17 and/or between the heatsink 12 and the circuit board 14, transfer to the control device housing 10. The TIM layers are reduced to a particular extent by said embodiment so that the heat transfer can be carried out particularly effectively. In addition, said embodiment guarantees effective protection of the processor 18 without an additional processor housing.

The heatsink 12 can be expediently embodied, in terms of shape, in such a way that heat is only partially connected to adjacent housing parts via narrow adhesive webs or free air gaps in order to transfer little heat there; adjacent parts, such as, e.g., memory parts (RAM, FLASH, oscillator), can be thermally connected via TIM to regions of the housing which are significantly cooler than regions which are under the direct heat influence of the power semiconductor or the performance GPU/MCU.

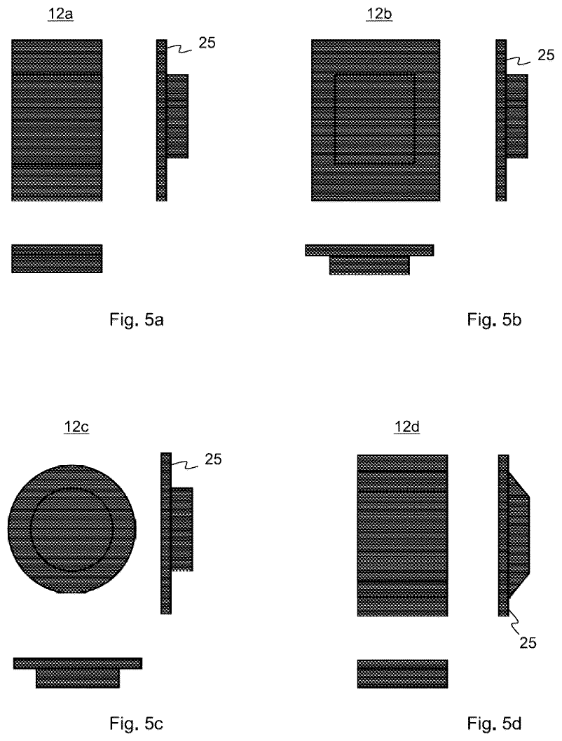

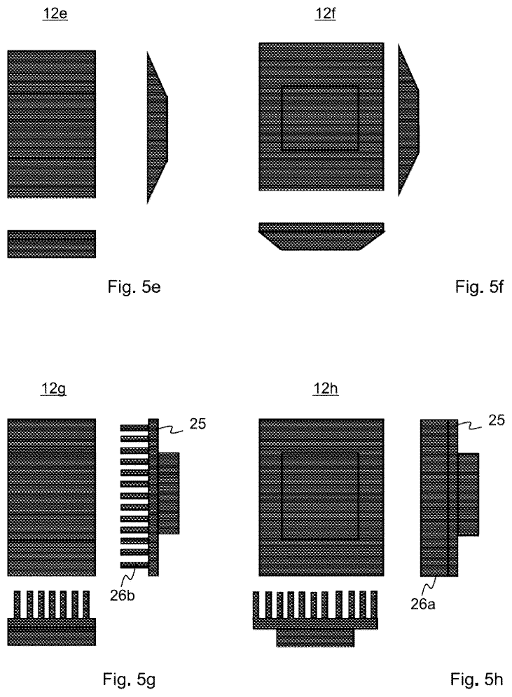

Embodiments of the first thermal component or of the heatsink 12 are shown in FIGS. 5a-5h, wherein a top view of the side facing the component to be cooled or facing the processor apparatus 15 as well as the associated side views are shown in each case. The heatsinks 12a-12d in FIGS. 5a-5d have a collar 25, wherein the tolerance-compensating material 13 can be arranged on the collar 25, wherein the collar 25 can then be fitted into a counterpart of the recess 11. Rhombohedral heatsinks 12e, 12f are shown in each case in FIGS. 5e-5f, which can be fitted into the recess 11 thanks to the tapered shape in profile, wherein the tolerance-compensating material 13 is also located on an edge of the recess 11 here as well.

A further embodiment of the heatsink is shown in FIG. 5g and FIG. 5h, in which a side of the heatsink 12g, 12h is equipped with continuous cooling fins 26a or individual cooling studs 26b, in a comparable manner to a construction of an air-cooled housing. The outward-facing side of the heatsink 12g, 12h can be flowed around by a liquid or gaseous fluid. In the case of liquid cooling, the heatsink 12g, 12h should then be glued in, in a liquid-tight manner. Furthermore, to this end, an impermeable cover can be provided above the fins, which seals the apparatus outwardly.

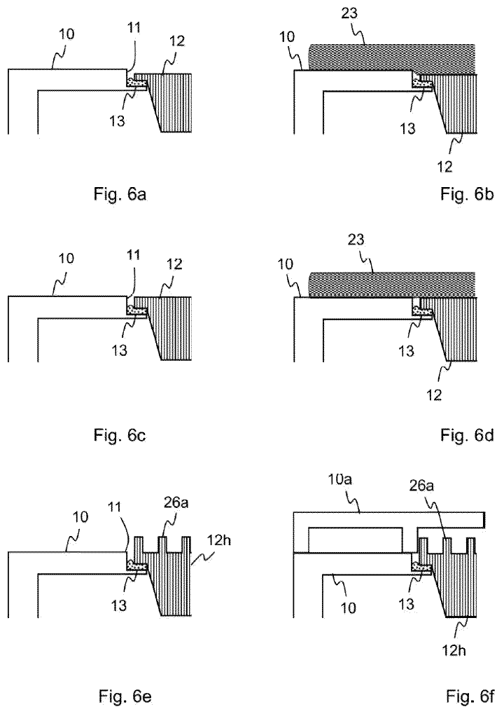

Various embodiments of the transition between the heatsink 12 and the control device housing 10 are shown in FIGS. 6a-6f. FIG. 6a shows a height offset between the heatsink 12 and the control device housing 10. In this case, a gap which may exist between the heatsink 12 or 12a and the control device housing 10 or the edge of the recess 11 can also be clearly seen. Said gap allows an installation aligned/lying in contact with the part 15 to be cooled and can also have an advantageous effect for thermal decoupling from the control device housing 10. Furthermore, tolerance-compensating material 13 can be located in the gap since it may possibly be pressed into the gap by the mounting of the heatsink 12 (as shown in FIGS. 6a-6f/this can likewise be the case in the other figures—however, this was not depicted for the sake of simplicity). Instead of on the heatsink 12 or on the control device housing 10, the, e.g., paste-like tolerance-compensating material 13 can also be dispensed directly into the gap in the region between the recess 11 and the heatsink 12 following the positioning of the heatsink 12. Furthermore, the cooling pad 23 can be provided as the second thermal component (as shown in FIG. 6b), which, due to its flexible properties, nestles against the control device housing 10 as well as against the heatsink 12 so that no further compensating material is necessary. According to an embodiment which is not depicted in the figures, the heatsink 12 could also have a projection (i.e., in contrast to the embodiment depicted in FIG. 6a) with regard to the control device housing 10 (i.e., the heatsink 12 could protrude beyond the control device housing 10), which, as it were, is compensated for by a cooling pad 23. An embodiment, in which the heatsink 12 and control device housing 10 form a virtually planar or flat surface, is shown in FIG. 6c. In the same way, a cooling pad 23 can likewise be provided here as the second thermal component, as shown in FIG. 6d. An embodiment, in which a heatsink 12h is provided, which has cooling fins 26a on the top, is shown in FIG. 6e. The heatsink 12h can dissipate heat via said cooling fins, since said cooling fins increase the surface of the heatsink 12h. In this case, an air or fluid flow can be utilized for cooling down. Here, the cooling fins or studs can be produced in a much more delicate manner and also from material having better thermally conductivity than can be done in the case of conventional housings. Furthermore, a cover 10a can also be provided, which, as depicted in FIG. 6f, is arranged above the control device housing 10 and the heatsink 12h, wherein cooling ducts are configured with cooling fins of the heatsink 12h between the cover 10a and the surface, as a result of which cooling fluid (e.g., air or coolant) can be conducted or conveyed, so that the heat can be effectively transported away by the heatsink 12h.

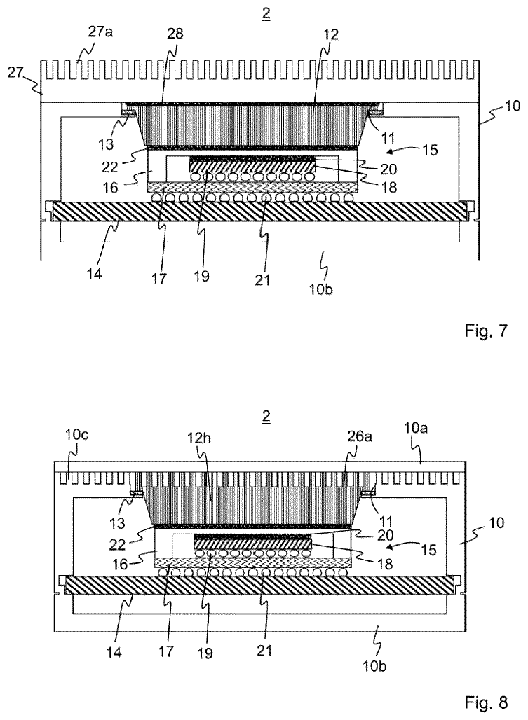

FIG. 7 shows an embodiment of the control device 2, in which a passive cooling block 27 having cooling fins 27a, which is air-cooled so to speak, e.g. via a fan or by natural convection or via an air flow, is provided as the second thermal component. In addition, the cooling block 27 is manufactured, e.g., from copper or aluminum, as a result of which it has a better thermal conductivity value than the remaining control device housing 10 if the latter is manufactured, e.g., from a poorly conductive aluminum alloy or plastic. Furthermore, a larger surface (larger than the surface located on the part to be cooled) is created on the outside by the cooling fins 27a guiding air thanks to the design of the cooling block 27. Height tolerances in relation to the control device housing 10 are, as a general rule, not critical in the case of such air systems, wherein the embodiment according to FIG. 7 shows that the heatsink 12 and the control device housing 10 form a substantially planar surface, on which the cooling block 27 is arranged. Furthermore, the heatsink 12 and the control device housing 10 do not form a smooth or flat surface, i.e., the heatsink 12 either protrudes beyond the control device housing 10 or, as shown in FIG. 7, the control device housing 10 protrudes beyond the heatsink 12, an additional layer of TIM 28 can be provided in order to compensate for any height differences, which is in particular more extensive/more voluminous than the layer of TIM 20, but nevertheless has a low thermal resistance.

An embodiment, in which the control device housing 10 has cooling fins 10c (or, alternatively, also cooling studs) as the additional cooling function, is shown in FIG. 8. Furthermore, a heatsink 12h having cooling fins 26a (or, alternatively, also cooling studs) is provided as the first thermal component. E.g., an air flow can be provided, which flows along the cooling fins 10c, 26a (or cooling studs) in order to cool them down. The air flow can be generated actively, e.g., by a fan, or passively. Moreover, it can also be provided that the cooling fins 10c, 26a (or cooling studs) are covered via the cover 10a so that a fluid duct system or fluid ducts between the cooling fins 10c, 26a (or cooling studs), through which fluid is either conveyed actively or passively. As a result, a liquid-cooled system can also be realized, for example, by closing off said fluid ducts in a fluid-tight manner and connecting them to a fluid circuit via an inlet and outlet.

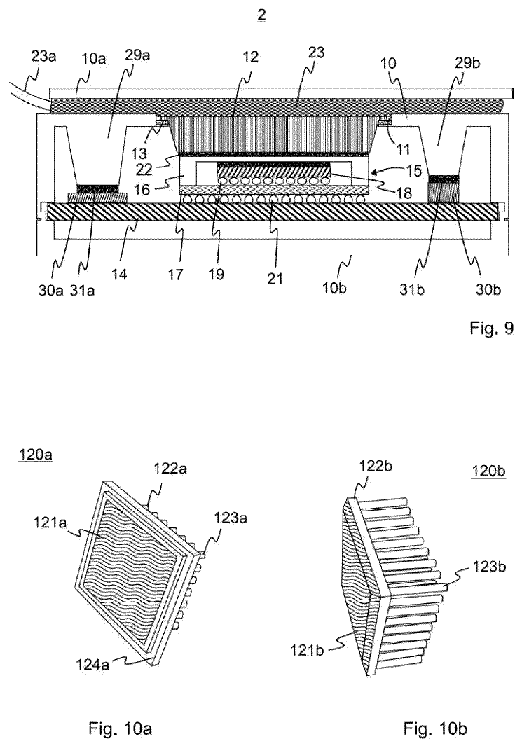

A further embodiment of a control device 2, in which other semiconductor parts 30a, 30b on the circuit board 14 are contacted via cooling units 29a, 29b in order to cool them down, is shown in FIG. 9. Comparatively thick TIM layers 31a, 31b are arranged in each case between the cooling units 29a, 29b and the semiconductor parts 30a, 30b (according to the conventional construction method). Furthermore, the control device housing 10 has a substantially flat area with a slight height offset (tolerance compensation for lying in close contact with the heat hotspot part) between the heatsink 12 and the control device housing 10, which is compensated for by the elasticity of a bellows through which liquid flows or of the cooling pad 23 through which liquid flows, and nestles against the control device housing 10 and the heatsink 12 without an appreciable gap and consequently dissipates the heat. The flow direction of the fluid in the cooling pad 23 flows through said cooling pad either in a kind of meandering shape or substantially perpendicular to the cutting direction of the image (i.e., not from left to right or vice versa in order to guarantee thermal decoupling of the heatsink 12 and cooling units 29a, 29b). Thanks to said embodiment, the thermal decoupling of the component to be cooled or the processor apparatus 15 and the other semiconductor parts 30a, 30b can be realized or improved in a particularly simple form.

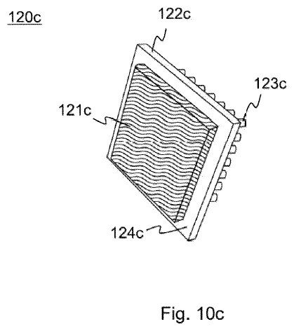

Embodiments of a heatsink 120a or 120b are shown in FIGS. 10a and 10b, which can be utilized for a cooling arrangement according to the embodiment or for a control device 2 according to the embodiment. The heatsink 120a or 121b is manufactured from an aluminum-copper composite material by means of a forming process, in particular extrusion, and has cooling studs 121a or 121b. The heatsink 120a and the heatsink 120b has copper 121a or 122b or a copper alloy toward the component to be cooled since copper has excellent thermal conduction properties, and aluminum 122a or 122b or an aluminum alloy toward the fluid cooling since aluminum is often very robust and, in addition, likewise has good thermal conduction properties with regard to the respective fluid cooling system. The heatsinks 120a and 120b substantially differ in that, in the case of the heatsink 120a, the copper layer 121a is embedded in the aluminum layer 122a or enclosed by said aluminum layer, and in the case of the heatsink 120b made of a copper layer 121b and an aluminum layer 122b, a type of layer package is formed.

Special embodiments having cooling studs 123a, 123b are, in each case, shown in FIGS. 10a/10b (which are likewise manufactured from aluminum or an alloy thereof). However, the heatsink could preferably have all forms such as, e.g., a collar 124a (as shown in FIG. 10a), a rhombohedral/trapezoidal cross-section (as shown in FIG. 10b) or cooling fins (as shown, by way of example, in FIG. 5h and FIGS. 6e/f). An embodiment of a heatsink 120c having a collar 124c is shown, by way of example, in FIG. 10c. In this case, the collar 124c can be formed in a simple manner in that, starting from a type of the embodiment according to FIG. 10a, the embedded copper layer 121a protrudes from the aluminum layer 122a or, starting from a type of the embodiment according to FIG. 10b, the area of the copper layer 121b is selected to be smaller than the area of the aluminum layer 122b, wherein, as a result, the copper layer 121c juts out beyond the aluminum layer 122c. In this case, extrusion is particularly well suited to producing the heatsink 120a, 120b, 120c, since the mold portions of copper 121a, 121b, 121c and aluminum 122a, 122b, 122c, can be connected to one another particularly well here. In this case, extrusion is one of the forming processes or mass forming, which can be carried out by a single-stage or multi-stage manufacturing operation.

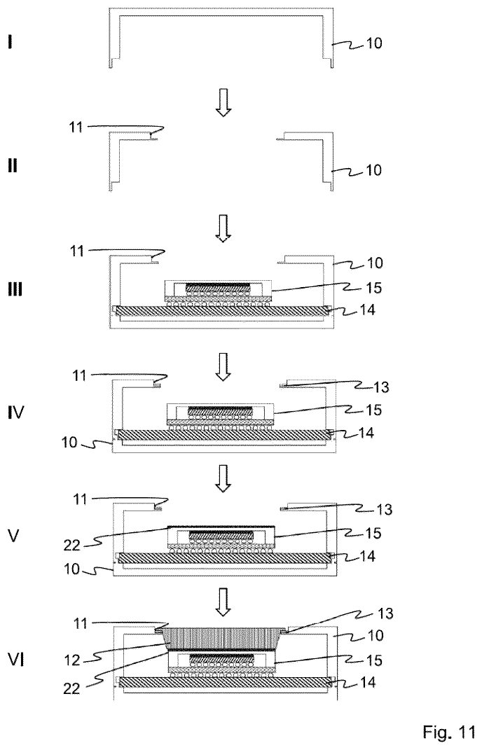

An embodiment of the gradual mounting of a cooling arrangement during the manufacture or an embodiment of a process for producing a cooling arrangement according to the embodiment is shown in FIG. 11. The process has the following process steps of: providing (I) a housing, in particular of the control device 2 (control device housing 10) with a recess 11, which substantially corresponds to the dimensions of the heatsink 12 and is located in the region or the alignment of the component to be cooled or providing (I) a control device housing 10, in particular of a control device 2, and producing a recess 11; mounting (III) the component to be cooled in the control device housing 10, e.g., by arranging, for example positioning, fastening or pushing in the circuit board 14 with a processor apparatus 15 (or IC module/processor 18) to be cooled arranged thereon in the control device housing 10. (In FIG. 11, the circuit board 14 is clamped between the control device housing 10 and the cover 10b); Applying (IV) a hardening tolerance-compensating material 13 (e.g., an adhesive or a paste) in order to secure the heatsink 12 on the control device housing 10 or at the edge of the recess 11; An application (V) of, e.g., a paste-like or liquid TIM 22 or a thin TIM pad to the power component to be cooled or the component to be cooled is expediently carried out, as well as Introducing (VI) the heatsink 12 (or heat spreader or cooling block), which is preferably manufactured from aluminum or copper or an alloy or a composite material thereof, into the recess 11 in such a way that the TIM 22 is displaced to a large extent on the component to be cooled and the heatsink 12 is only fixed by the hardening of the tolerance-compensating material 13 (or of the adhesive or another “fixing medium”).

In summary, the embodiment shows multiple parts of the solution, as a result of which one or more TIM layer thicknesses can be decreased to a particular extent or can even be optionally omitted. As a result, the thermal resistances are decreased. In addition, according to some embodiments, the thermal coupling of the main heat generator (e.g., of the high-performance processor) to other components (e.g., the storage modules) can be reduced. Furthermore, the transfer area of the thermal hotspot can be significantly increased in the direction of the heat-dissipating medium by the embodiment. The novel concept is suitable for special liquid-cooling systems, but also for specially embodied air-cooling systems. Furthermore, the embodiment discloses how, when the cooling element (i.e., the heat spreader or heatsink) is a minimum distance from the part to be cooled (component to be cooled) or the TIM layer thereon, the mechanical support is effected on the solid housing part and not on the component to be cooled which is as, a general rule, mechanically sensitive.

Of course, the cooling apparatus can also be deployed for heating a component to be heated (so to speak, as a heating apparatus) by filling said apparatus with a medium which emits heat to a component to be heated. To this end, the cooling apparatus can be easily connected to a heating circuit via the connections in order to be supplied with a heating medium which then flows through the cooling apparatus or heating apparatus. For example, the rack according to the embodiment or the cooling arrangement according to the embodiment could also be deployed for heating one or more subassemblies, in particular in the automotive sector.

1. A cooling arrangement, comprising
a housing;
a component to be cooled arranged in the housing; and
a first thermal component arranged on the component to be cooled; and
a tolerance-compensating material provided between the first thermal component and the housing,
wherein the housing comprises a recess into which the first thermal component is inserted in such a way that the first thermal component is mechanically aligned with the component to be cooled and is thermally coupled thereto.

2. The cooling arrangement according to claim 1, wherein the tolerance-compensating material is a hardening material.

3. The cooling arrangement according to claim 2, further comprising a second thermal component arranged on at least one of the housing and the first thermal component.

4. The cooling arrangement according to claim 3, further comprising a thermal interface material arranged between the first thermal component and the second thermal component or between the first thermal component and the component to be cooled.

5. The cooling arrangement according to claim 4, wherein the first thermal component comprises a heatsink,
wherein the heatsink comprises a collar, and
wherein the tolerance-compensating material is arranged on the collar.

6. The cooling arrangement according to claim 5, wherein the heatsink has a trapezoidal or rhombohedral cross-section.

7. The cooling arrangement according to claim 6, wherein the heatsink comprises cooling fins or cooling studs.

8. The cooling arrangement according to claim 7, wherein the second thermal component comprises a heat pipe or fluid cooling with fluid ducts or air cooling with cooling fins or a fluid plate with fluid ducts.

9. The cooling arrangement according to claim 7, wherein the second thermal component is an elastic bellows or a cooling pad, which is at least partially manufactured from flexible material, so that the second thermal component or a flexible part of the second thermal component nestles against the first thermal component.

10. The cooling arrangement according to claim 9, wherein the flexible material comprises at least one of metal film of aluminum or copper, and/or plastic film and/or a laminate and/or a composite film of a metal film and a plastic film.

11. The cooling arrangement according to claim 10, wherein the second thermal component is filled with a cooling medium or is flowed through by a cooling medium and a fluid comprising water, glycol, a water/glycol mixture, air, or CO2 as the cooling medium.

12. The cooling arrangement according to claim 11, further comprising tolerance-compensating material arranged between the first thermal component and the second thermal component and/or a circuit board which carries the component to be cooled and/or the component to be cooled.

13-16. (canceled)
